(19) United States
(12) Patent Application Publication
(10) Pub. No.: US 2013/0240990 A1
(43) Pub. Date: Sep. 19, 2013

(54) SEMICONDUCTOR STRUCTURE AND METHOD FOR MANUFACTURING THE SAME

(71) Applicants: Haizhou Yin, Poughkeepsie, NY (US); Wei Jiang, Sanming (CN); Gaobo Xu, Beijing (CN)

(72) Inventors: Haizhou Yin, Poughkeepsie, NY (US); Wei Jiang, Sanming (CN); Gaobo Xu, Beijing (CN)

(21) Appl. No.: 13/989,808

(22) PCT Filed: Dec. 2, 2011
(86) PCT No.: PCT/CN2011/083331

§ 371 Date: May 27, 2013

(30) Foreign Application Priority Data
Nov. 15, 2011 (CN) 201110362350.9

(51) Int. Cl. H01L 29/40; H01L 29/417

(52) U.S. Cl. CPC H01L 29/401; H01L 29/41775
USPC 257/343; 438/300

(57) ABSTRACT

A method for manufacturing a semiconductor structure and a semiconductor device manufactured using the same are disclosed. In replacement gate process, the present invention is capable of reducing contact resistance at source/drain regions through forming doped amorphous Si layers above source/drain regions, forming contact holes (310) penetrating through the interlayer dielectric layer (300) and amorphous Si layers (251); wherein the contact holes (310) at least expose part of the source/drain regions (110), and contact layers are formed at the exposed area of the source/drain regions and sidewalls of the contact holes in the amorphous Si layer. Since contact layers are formed after high-k dielectric layer has been annealed, metal silicide layers are protected from damages at high temperatures.

The present application claims priority benefit of Chinese patent application No. 201110362350.9, filed on 15 Nov. 2011, entitled “SEMICONDUCTOR STRUCTURE AND METHOD FOR MANUFACTURING THE SAME”, which is herein incorporated by reference in its entirety.

### FIELD OF THE INVENTION

The present invention relates to the field of semiconductor manufacturing, particularly, to a semiconductor structure and a method for manufacturing the same.

### BACKGROUND OF THE INVENTION

Metal-Oxide-Semiconductor Field-Effect Transistor (MOSFET) is a kind of transistors that can be widely applied in digital circuits and analog circuits. When gate dielectric layers of MOSFET is made of high-k dielectric material, Gate leakage currents can be effectively reduced. However, when a high-k dielectric layer is formed, the molecular structure of the high-k dielectric layer may have slight defects. In order to repair such defects, it may be necessary to anneal the high-k dielectric layer at a relatively high temperature (600° C.-800° C.). In addition, annealing of the high-k dielectric layer can improve reliability of transistors. In the replacement gate process, a high-k gate dielectric layer is usually deposited after removal of dummy gates, for example, after deposition of interlayer dielectric layers. If metal silicide has already formed at source/drain regions at that time, the structure of the metal silicide layer may be changed due to the high temperature necessary to anneal the high-k dielectric layer, and electrical resistivity of the metal silicide layer may increase, which thereby may reduce performance of the transistor.

The prior art, US patent application numbered US2007/0141798A1, has proposed a method, which can implement annealing treatment to high-k gate dielectric layers without damaging metal silicide layers, wherein the method comprises following steps:

forming a transistor with a sacrificial gate on a substrate, depositing a first interlayer dielectric (ILD) layer on the substrate, removing the sacrificial gate to form a gate trench, depositing a high-k dielectric layer within the gate trench, annealing the high-k dielectric layer, depositing a first metal layer within the gate trench, depositing a second ILD layer on the first ILD layer and the transistor, etching the first and second ILD layers to form individually a first contact trench and a second contact trench that extend down to a source region and a drain region of the transistor, depositing a second metal layer within the contact trenches, annealing the second metal layer to form metal silicide layers on the source and drain regions, and depositing a third metal layer within the first and second contact trenches to fill the contact trenches.

Contact layers (e.g. metal silicide layers) are formed after annealing high-k dielectric layers, and thereby the metal silicide layers are protected from damage due to high temperature.

Although aforesaid method will not cause damage to metal silicide layers at the time of annealing high-k gate dielectric layers, the method has limitations in that metal silicide layers are formed only between the contact trenches and source/drain regions, and thus the area of source/drain regions covered by metal silicide layers is limited, so that contact resistance of metal silicide layers of the transistor may not be significantly decreased. Therefore, how to reduce contact resistance of contact layers (e.g. metal silicide layers) is still a problem that needs to be solved.

### SUMMARY OF THE INVENTION

The present invention aims to provide a semiconductor structure and a method for manufacturing the same, which are favorable for reducing contact resistance of contact layers (e.g. metal silicide layers) at source/drain regions.

In one aspect, the present invention provides a method for manufacturing a semiconductor structure, comprising:
a) providing a substrate;
b) forming a dummy gate stack on the substrate, spacers located on sidewalls of the dummy gate stack, and source/drain regions located on both sides of the dummy gate stack; wherein the dummy gate stack at least comprises a first gate dielectric layer and a dummy gate;
c) forming an amorphous Si layer, which has the same doping type as the source/drain regions, on surfaces of the source/drain regions;
d) forming an interlayer dielectric layer to cover the doped amorphous Si layer and the dummy gate stack;
e) removing part of the interlayer dielectric layer to expose the dummy gate stack;
f) removing the dummy gate stack to form an opening, filling the opening with a second gate dielectric layer and a first conductive material, or removing part of the dummy gate stack that is located on the first gate dielectric layer to form an opening, and filling the opening with a first conductive material, so as to form a gate stack structure;
g) forming contact holes that penetrate through the interlayer dielectric layer and the amorphous Si layer; wherein the contact holes at least expose part of the source/drain regions;
h) forming a contact layer on the exposed part of the source/drain regions and on sidewalls of the contact holes in the amorphous Si layer; and
i) filling the contact holes with a second conductive material to form contact vias.

In another aspect, the present invention further provides a semiconductor structure, which comprises:
a substrate;
a gate stack structure formed on the substrate;
source/drain regions formed within the substrate and located on both sides of the gate stack structure;
an amorphous Si layer covering the source/drain regions;
an interlayer dielectric layer covering the amorphous Si layer and the gate stack structure; and
contact vias, which are formed with a second conductive material, penetrating through the interlayer dielectric layer and the amorphous Si layer and being electrically connected with the source/drain regions; wherein,

a contact layer is formed between the contact vias and the source/drain regions, and between the contact vias (320) and the amorphous Si layer.

In the present invention, a contact layer is formed on surfaces of source/drain regions and the amorphous Si layer. Since the metal silicide contact layer needs not to experience high-temperature treatment for high-k gate dielectric layers, the thickness of the formed contact layer may be controlled to be greater than that that after high-temperature treatment, and contact resistance of the metal silicide layer at source/drain regions are reduced. Meanwhile, the area of source/drain regions covered by contact layers is increased, which is also favorable for reducing contact resistance at source/drain regions. Further, the contact area between source/drain regions and the contact layer is increased owing to presence of the amorphous Si layer, and this may further reduce contact resistance. As compared to the prior art, the present invention has significant progress and improvements.

### BRIEF DESCRIPTION OF THE DRAWINGS

Additional characteristics and advantages of the present invention are made more obvious and easily understood according to perusal of the following detailed description of exemplary embodiment(s) in conjunction with accompanying drawings, wherein:

FIG. 1 illustrates a flowchart of a method for manufacturing a semiconductor structure according to the present invention; and

FIG. 2 to FIG. 13 illustrate cross-sectional structural diagrams of the semiconductor structure at respective stages of a method for manufacturing a semiconductor structure according to the flowchart of a preferred embodiment of the present invention as shown in FIG. 1.

Same or similar reference numbers in accompanying drawings denote same or similar elements.

### DETAILED DESCRIPTION OF THE INVENTION

Embodiments of the present invention are described in detail here below, wherein examples of embodiments are illustrated in drawings. It should be appreciated that the embodiments described below in conjunction with drawings are illustrative and are provided for explaining the prevent invention only, thus shall not be interpreted as limitations to the present invention.

Various embodiments or examples are provided here below to achieve different structures of the present invention. To simplify disclosure of the present invention, description of components and arrangements of specific examples is given below. Of course, they are illustrative only and not limiting the present invention. Moreover, in the present invention, reference numbers and/or letters may be repeated in different embodiments. Such repetition is for purposes of simplicity and clarity, yet does not denote any relationship between respective embodiments and/or arrangements being discussed. Furthermore, the present invention provides various examples for specific process and materials. However, it is obvious for a person of ordinary skill in the art that other processes and/or materials may be utilized alternatively. In addition, the following structure in which a first feature is “on/above” a second feature may include an embodiment in which the first feature and the second feature are formed to be in direct contact with each other, and may also include an embodiment in which another feature is formed between the first feature and the second feature such that the first and second features might not be in direct contact with each other.

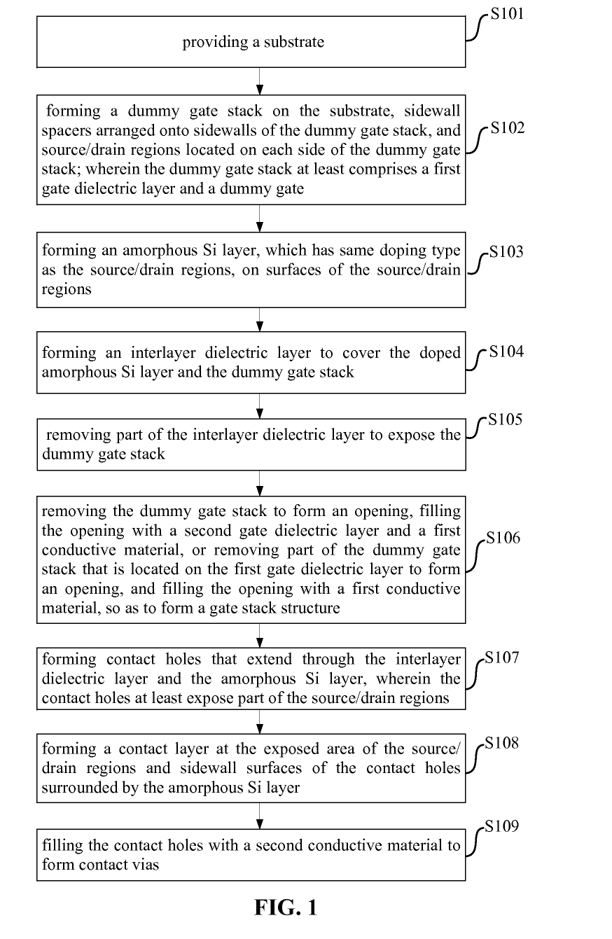

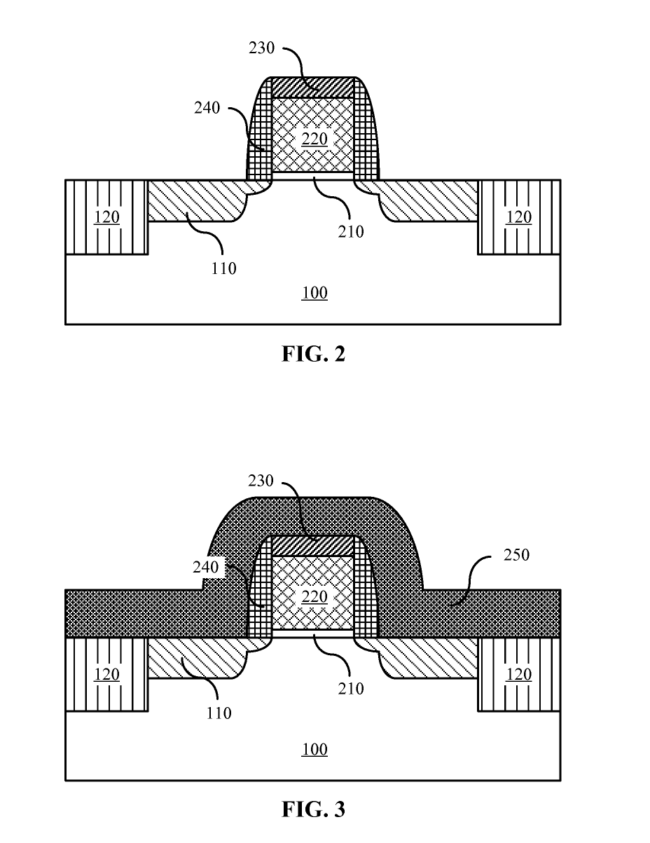

Here blow, the method for manufacturing a semiconductor structure as show in FIG. 1 is described in detail with reference to FIG. 2 to FIG. 13.

With reference to FIG. 1 and FIG. 2, a substrate 100 is provided at step S101.

In the present embodiment, the substrate 100 includes Si substrate (e.g. Si wafer). According to design specifications known in the prior art (e.g. a P-type substrate or an N-type substrate), the substrate 100 may be of various doping configurations. The substrate 100 in other embodiments may further include other semiconductor, for example germanium, or a compound semiconductor (e.g. material of III-V families) like SiC, GaAs, InAs. Typically, the substrate 100 may have, but is not limited to, a thickness of about several hundred micrometers, which for example may be in the range of 400 μm-800 μm.

Specifically, an isolation region may be formed within the substrate 100, for example, a Shallow Trench Isolation (STI) structure 120, so as to electrically isolate neighboring Field-Effect transistor devices.

With reference to FIG. 1 and FIG. 2, at step S102, a dummy gate stack is formed on the substrate 100, spacers 240 are formed to be located on sidewalls of the dummy gate stack, and source/drain regions 110 are formed on both sides of the dummy gate stack; wherein, the dummy gate stack comprises a first gate dielectric layer 210, a dummy gate 220 and a cap layer 230.

In the present embodiment, at formation of the dummy gate stack, a first gate dielectric layer 210 is firstly formed on the substrate 100. In the present embodiment, the material of the first gate dielectric layer 210 may be SiO₂, Si₃N₄ or a combination thereof, or may be high-k dielectric in other embodiments, which, for example, may comprise a material selected from a group consisting of HfO₂, HfSiO, HfSiON, HfTaO, HfTiO, HfZrO, Al₂O₃, La₂O₃, ZrO₂ and LaAlO, or combinations thereof. The thickness of the first gate dielectric layer 210 may be 2-10 nm. Then, a dummy gate 220 is formed on the first gate dielectric layer 210 by depositing, for example, Poly-Si, Poly-SiGe, amorphous Si, and/or doped or undoped SiO₂, Si₃N₄, SiOₓN_{y}, SiC, even a metal, and the thickness thereof may be 10-80 nm. Finally, a cap layer 230 is formed on the dummy gate 220 by way of, for example, depositing Si₃N₄, SiO₂, SiOₓN_{y}, SiC and combinations thereof, for purposes of protecting the top of the dummy gate 220, and preventing the top of the dummy gate 220 from reacting with metal layers to be deposited at subsequent processes for forming contact layers. The cap layer 230 may not be formed in other embodiments. Accordingly, the dummy gate stack is formed through patterning by means of lithography and etching aforesaid multi-layer structure. In another embodiment, it is also applicable that the dummy gate stack does not comprise a first gate dielectric layer 210. Instead, a gate dielectric layer is formed after removing the dummy gate stack in subsequent replacement gate processes.

After formation of the dummy gate stack, spacers 240 are formed to be located on sidewalls of the dummy gate stack for isolating the gate. The spacers 240 may be made of a material selected from a group consisting of Si₃N₄, SiO₂, SiOₓN_{y} and SiC, or combinations thereof, and/or other materials as appropriate. The spacers 240 may have a multi-layer structure in which neighboring layers may be made of different materials. The spacers 240 may be formed by depositing and etching processes to have a thickness in a range of about 10 nm-100 nm, for example, 30 nm, 50 nm or 80 nm.

Source/drain regions 110 are located on both sides of the dummy gate stack, and may be formed by implanting P-type or N-type dopants into the substrate 100. For example, for PMOS, the source/drain regions 110 may be made of P-type doped SiGe; and for NMOS, the source/drain regions 110 may be made of N-type doped Si. Source/drain regions 110 may be formed by means of lithography, ion implantation, diffusion and/or other processes as appropriate. The semiconductor structure is annealed by conventional semiconductor manufacturing processes and steps, so as to activate dopants in source/drain regions 110. The annealing process may be rapid annealing, spike annealing or other methods as appropriate. In the present embodiment, source/drain regions 110 are located within the substrate 100. While in other embodiments, the source/drain regions 110 may be raised source/drain structures formed by selective epitaxial growing, wherein the top of the epitaxial portions thereof are higher than the bottom of the dummy gate stack (herein, the bottom of the dummy gate stack indicates the boundary between the dummy gate stack and the substrate 100).

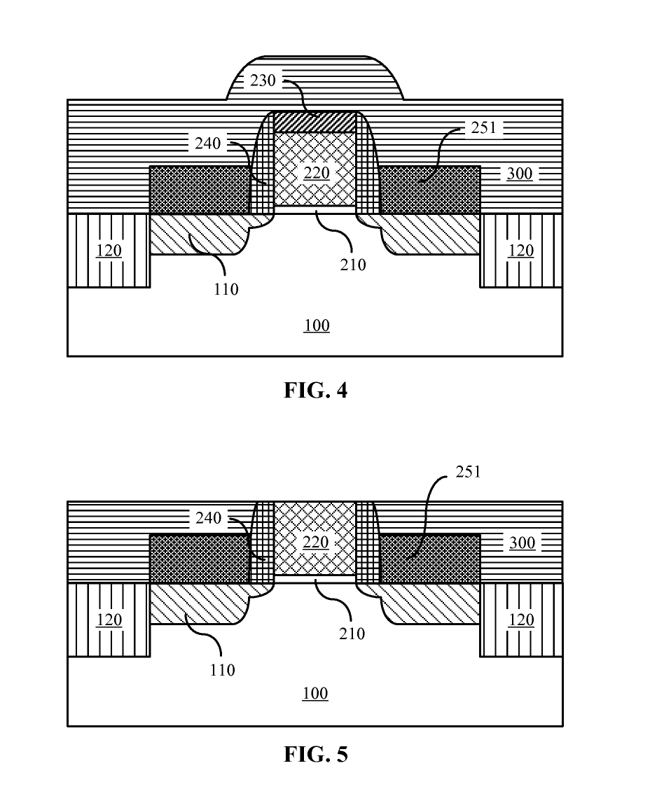

With reference to FIG. 1, FIG. 3 and FIG. 4, an amorphous Si layer 251 with the same doping type as the source/drain regions is formed on surfaces of the source/drain regions 110 at step S103. Specifically, as shown in FIG. 3, a amorphous Si layer 250 is firstly deposited to cover the surface of the substrate 100, i.e., as shown in the figures, to cover the dummy gate stack, spacers 240 and source/drain regions 110. The amorphous Si layer 250 may be formed by means of Chemical Vapor Deposition (CVD), plasma enhanced CVD, High-density plasma CVD, atomic layer deposition (ALD), plasma enhanced atomic layer deposition (PEALD), pulsed laser deposition (PLD), or other methods as appropriate. The thickness of the amorphous Si layer 250 may vary from several nanometer to dozens of nanometer. Then, the amorphous Si layer 250 is doped. If source/drain regions is P-type doped, the amorphous Si layer 250 is also P-type doped. And if source/drain regions is N-type doped, the amorphous Si layer 250 is also N-type doped, such that the amorphous Si layer 250 and source/drain regions have the same doping type. At last, a photoresist layer is applied on the amorphous Si layer 250 and patterned by lithography, and then the amorphous Si layer 250 located on portions other than the source/drain regions 110 is removed by means of etching, so as to form the doped amorphous Si layer 251 only located on the source/drain regions 110, as shown in FIG. 4.

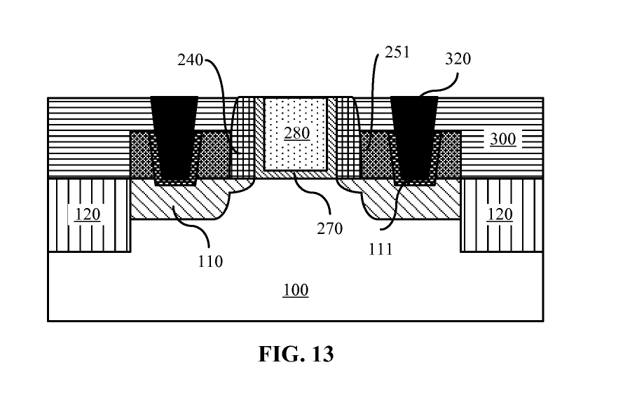

It should be noted that, in this case, at least part of the spacers 240 may be further removed before the amorphous Si layer 250 is covered. As shown in FIG. 13, the contact holes may be expanded at the time when manufacturing contact vias in subsequent steps. The larger the contact hole is, the larger the contact area of the source/drain regions and the contact layer 111 is, which thereby can reduce contact resistance between source/drain regions and the contact layer 111.

With reference to FIG. 1 and FIG. 4, at step S104, an interlayer dielectric layer 300 is formed to cover the doped amorphous Si layer (251) and the dummy gate stack. The interlayer dielectric layer 300 may be formed by means of chemical vapor deposition (CVD), plasma enhanced CVD, high-density plasma CVD, spin coating and/or other methods as appropriate. The interlayer dielectric layer 300 may comprise a material selected from a group consisting of USG, doped USG (e.g. FSG, BSG, PSG, BPSG) and low-k dielectric materials (e.g. black diamond, coral), or combinations thereof. The thickness of the interlayer dielectric layer 300 may be in the range of about 40 nm-150 nm, for example, 80 nm, 100 nm or 120 nm, and the interlayer dielectric layer 300 may have a multi-layer structure (neighboring layers of which may be made of different materials).

With reference to FIG. 1 and FIG. 5, at step S105, part of the interlayer dielectric layer 300 is removed to expose the dummy gate stack.

In the present embodiment, a replacement gate process is performed. With reference to FIG. 5, the interlayer dielectric layer 300 and the dummy gate stack are planarized to expose the upper surface of the dummy gate 220. For example, the interlayer dielectric layer 300 may be removed by means of Chemical Mechanical polish (CMP), such that the upper surfaces of the dummy gate 220 and the interlayer dielectric layer 300 are flushed (herein, the term “flushed” means that the difference between heights of two objects is in the tolerance of technical error).

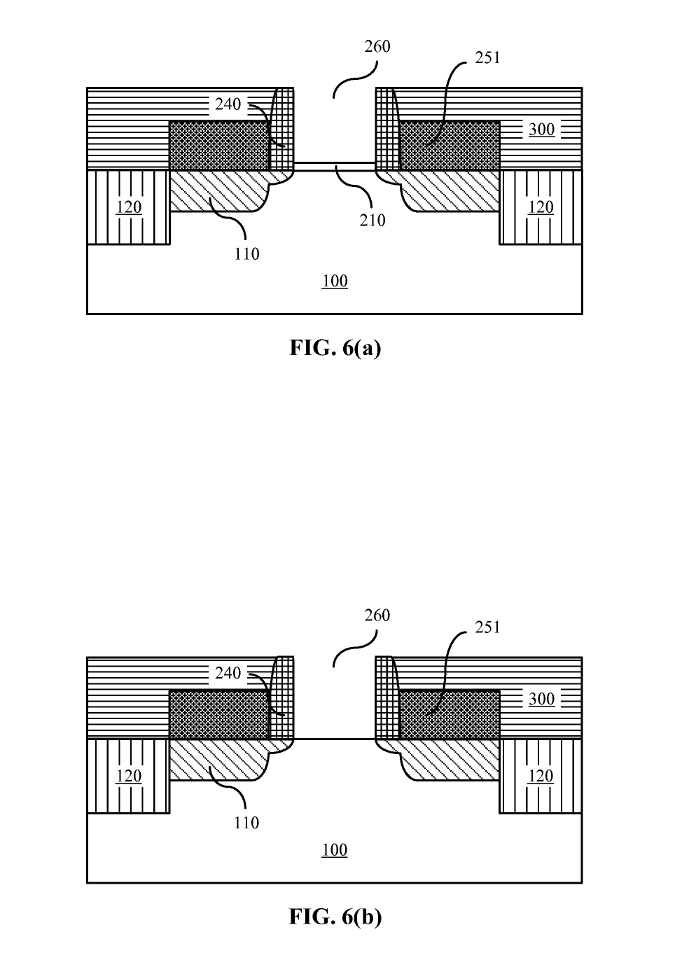

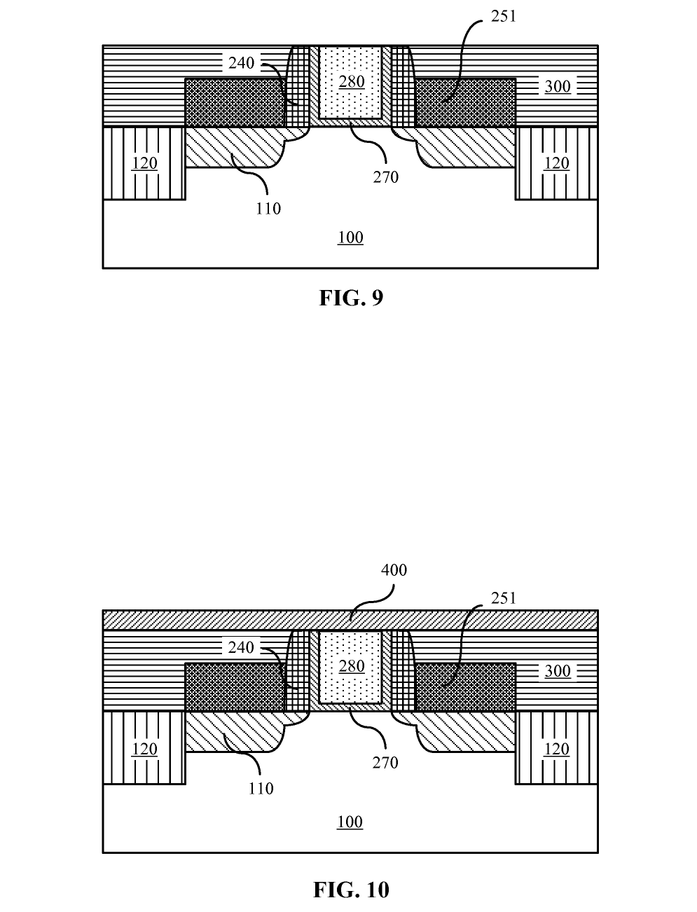

With reference FIG. 1, FIG. 6 and FIG. 9, at step S106, the dummy gate stack is removed to form an opening 260, in which a second gate dielectric layer and a first conductive material are filled. Alternatively, the part of the dummy gate stack located on the first gate dielectric layer is removed to form an opening, in which a first conductive material is filled, so as to form a gate stack structure.

In the present embodiment, the dummy gate 220 and the first gate dielectric layer 210 are removed together so as to expose the gate substrate 100 and to form an opening 260, as shown in FIG. 6(b). Wet etching and/or dry etching may be used to remove the dummy gate 220 and the first gate dielectric layer 210. In the wet etching, TMAH, KOH or other solutions as appropriate may be used. And in the dry etching, SF₆, HBr, HI, Cl, Ar, He, CH₄ (and CHₓCl₄₋ₓ), and hydrocarbons like C₂H₂, C₂H₄, or combinations thereof, and/or other materials as appropriate may be used.

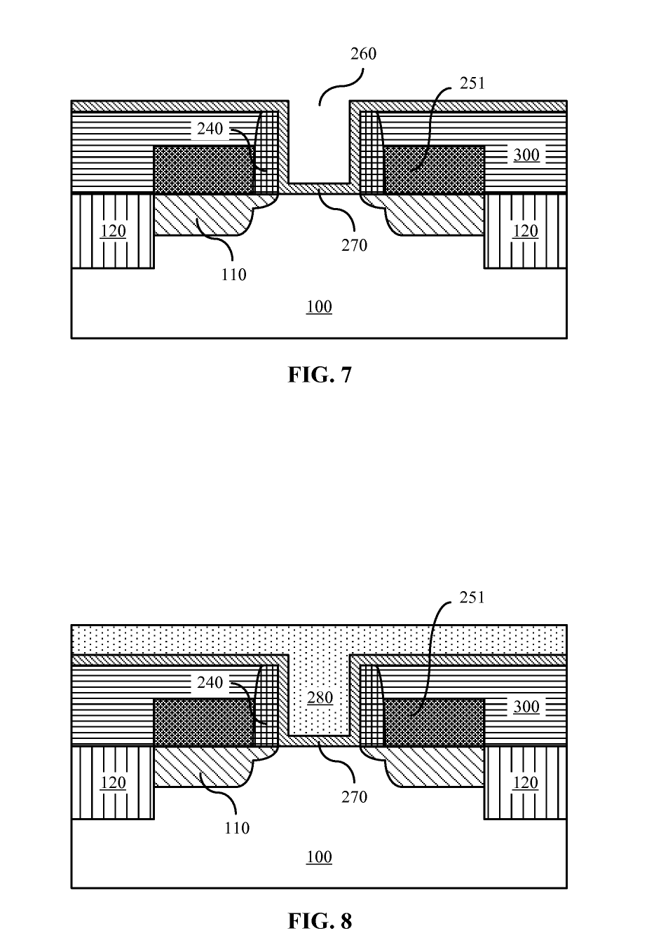

A gate dielectric layer 270 is deposited to cover the bottom of the opening 260 and inner walls of spacers 240, as shown in FIG. 7. The gate dielectric layer 270 may comprise high-k dielectrics, for example, a material selected from a group consisting of HfO₂, HfSiO, HfSiON, HfTaO, HfTiO, HfZrO, Al₂O₃, La₂O₃, ZrO₂ and LaAlO or combinations thereof, and the thickness thereof may be about 2 nm-10 nm, for example, 5 nm or 8 nm. The gate dielectric layer 270 may be formed by means of CVD or atomic layer deposition (ALD). The gate dielectric layer 270 may further have a multi-layer structure, which may comprise more than two layers made of abovementioned materials.

Annealing is further performed after formation of the gate dielectric layer 270 so as to improve performance of the semiconductor structure, and the annealing temperature is in the range of about 600° C. to 800° C. After annealing, a metal gate 280 is formed on the gate dielectric layer 270 by depositing a first conductive material, as shown in FIG. 8. For NMOS, the first conductive material may comprise a material selected from a group consisting of TaC, TiN, TaTbN, TaErN, TaYbN, TaSiN, HfSiN, MoSiN, RuTaₓ and NiTaₓ or combinations thereof. And for PMOS, the first conductive material may comprise a material selected from a group consisting of MoNₓ, TiSiN, TiCN, TaAlC, TiAlN, TaN, PtSiₓ, Ni₃Si, Pt, Ru, Ir, Mo, HfRu and RuOₓ or combinations thereof. The thickness thereof may be about 10 nm-80 nm, for example, 30 nm or 50 nm. The metal gate 280 may also have a multi-layer structure, which may comprise more than two layers made of abovementioned materials.

In other embodiments, in case the first gate dielectric layer 210 comprise a high-k dielectric material, which is, for example, selected from a group consisting of HfO₂, HfSiO, HfSiON, HfTaO, HfTiO, HfZrO, Al₂O₃, La₂O₃, ZrO₂and LaAlO or combinations thereof, it is also applicable to only remove the dummy gate 220 to form the opening 260, as shown in FIG. 6(a). Next, the first gate dielectric layer 210 is annealed at a high temperature so as to repair the structure formed prior to formation of the first conductive material, and then the metal gate 280 is formed. The processes of high-temperature annealing and forming of the metal gate are the same as the processes for forming the gate dielectric layer 270, and thus are not described here in detail.

Finally, CMP planarization is performed such that the upper surfaces of the metal gate 280 and the interlayer dielectric layer 300 are flushed to form the gate stack structure, as shown in FIG. 9.

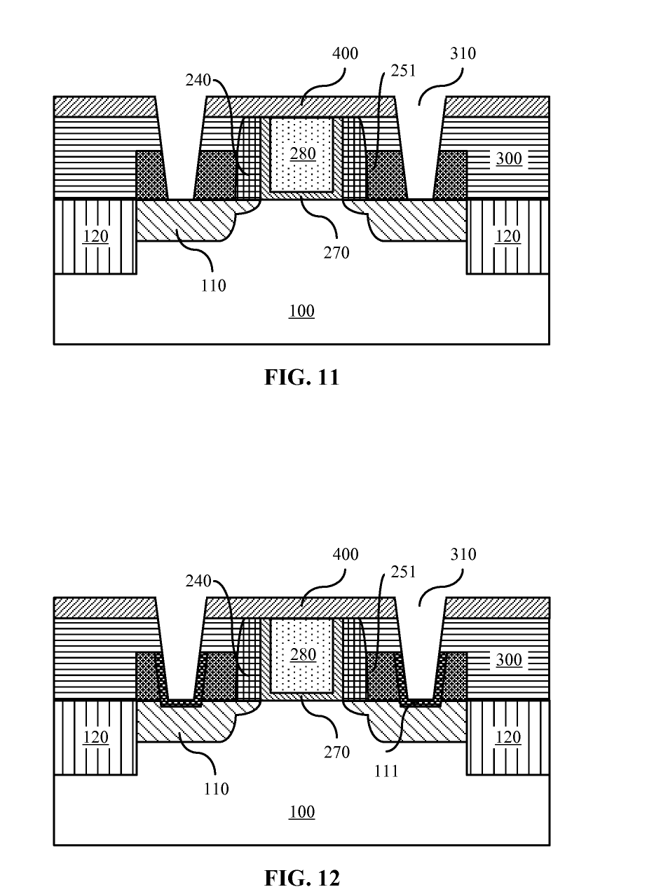

With reference to FIG. 1 and FIG. 11, contact holes 310 penetrating through the interlayer dielectric layer 300 and the amorphous Si layer 251 are formed at step S107, wherein the contact holes 310 at least expose part of the source/drain regions 110. In the present embodiment, the interlayer dielectric layer 300 is etched firstly, and the doped amorphous Si layer 251 is then etched till the source/drain regions 110 are exposed, thereby forming the contact holes 310.

A photoresist layer is applied on the interlayer dielectric layer 300 and the metal gate 280 before etching. Then the photoresist layer is exposured and patterned processes to form holes at positions where contact holes 310 are to be formed. In the present embodiment, the interlayer dielectric layer 300 and the doped amorphous Si layer 251 are etched respectively The etching stops at the surface where the source/drain regions 110 and the doped amorphous Si layer 251 come into contact, so as to form contact holes 310. Wherein, different etching methods and/or etching solutions may be used to etch the interlayer dielectric layer 300 and the doped amorphous Si layer 251. For example, in a case where the amorphous Si layer has a small thickness, dry etching may be used to etch the interlayer dielectric layer 300, while wet etching may be used to etch the doped amorphous Si layer 251. The photoresist layer may comprise a material selected from a group consisting of vinyl monomer, quinone azide compound and Polyethylene monolaurate, or any other appropriate materials selected according to manufacturing requirements in practice. The contact holes 310 formed by etching may have an inverted taper shape.

In embodiments of the present invention, the etching depth may be controlled. Specifically, when the doped amorphous Si layer 251 is etched, the etching time may be shortened or extended. Shorter etching time makes bottoms of the contact holes 310 only reach into the amorphous Si layer, while longer etching time makes bottoms of the contact holes 310 reach into the source/drain regions, such that the area exposed in the source/drain regions is further increased, which thereby may further reduce contact resistance between source/drain regions and the metal silicide layer in subsequent steps.

Optionally, prior to formation of contact holes 310, a cap layer 400 is deposited on the interlayer dielectric layer 300 and the metal gate 280, as shown in FIG. 10. The cap layer 400, which may be made of Si₃N₄, oxide or a combination thereof, is formed on the interlayer dielectric layer 300 and the metal gate 280 by means of CVD, plasma enhanced CVD, high-density plasma CVD, spin coating or other methods as appropriate. The cap layer 400 can protect the metal gate 280 from damages in subsequent processes of forming the semiconductor structure. In this case, the material of the cap layer shall be different from the material of the interlayer dielectric layer. For example, in subsequent processes, after a metal layer is deposited into contact holes 310 to form a metal silicide layer, the cap layer 400 can effectively protect the metal gate 280 from being etched by selectively removing the unreacted metal layer by etching.

In embodiments of the present invention, if the cap layer 400 has been deposited, etching process for forming contact holes 310 needs to be adjusted accordingly. For example, different etching gases may be used to etch the cap layer 400 and the interlayer dielectric layer 310, respectively.

With reference to FIG. 1 and FIG. 12, at step S108, contact layers 111 are formed at the exposed areas of the source/drain regions 110 and sidewalls of the contact holes 310 in the amorphous Si layer 251. A metal layer may be formed at bottom of the contact holes 310 by means of metal sputtering or chemical vapor deposition. In the present embodiment, the metal layer may comprise a material of Ni or NiPt, and the thickness thereof may be in the range of 10 nm-25 nm, for example. The metal silicide layers 111, which are formed after the metal layers react with Si at annealing, may comprise a material of NiSi or Ni(Pt)Si_{2-y}. In other embodiments, the metal layer may be made of any other metals as appropriate. Then, the semiconductor structure is annealed. The annealing may include rapid annealing, spike annealing and other methods as appropriate, such that part of the deposited metal layers, which is in contact with exposed areas of the source/drain regions 110 and sidewalls of the contact holes 310 in the amorphous Si layer 251, reacts with Si to form metal silicide layers 111.

As shown in FIG. 12, metal silicide layers 111 are formed at the exposed areas of the source/drain regions 110 and on sidewalls of contact holes 310 in the amorphous Si layer 251. Resistivity of the metal silicide layers 111, which may be made of different materials with different thicknesses at different temperatures, may vary remarkably. According to the above analysis, the thickness of the metal layers and the thickness of the metal silicide layers are determined in order to guarantee resistivity thereof to be at a quite low level.

With reference to FIG. 1 and FIG. 13, step S109 is performed. Contact metals (which may be referred to as “second conductive materials” hereinafter) are filled into the contact holes 310 to form contact vias 320. The contact metals may be a metal like W, TiAl, Al or an alloy. Optionally, prior to filling the contact holes 310 with a contact metal, a liner (not shown) may be deposited on the entire interior walls and bottom of the contact holes 310 by means of deposition processes like ALD, CVD, PVD. The liner may comprise a material selected from a group consisting of Ti, TiN, Ta and TaN or combinations thereof, and the thickness thereof is in the range of about 5 nm-20 nm, for example, 10 nm or 15 nm. After the contact metal is filled, the contact metal is processed by means of CMP planarization, such that the upper surface of the contact metal is flushed with the upper surface of the interlayer dielectric layer 300.

Then, manufacturing of the semiconductor device is finished according to conventional semiconductor manufacturing processes.

After completion of aforesaid steps, the metal silicide formed in the semiconductor structure does not need to experience high-temperature treatment necessary for high-k gate dielectric, and thus the thickness of the metal silicide may be controlled, which therefore reduces contact resistance between source/drain regions and the metal silicide layer. Additionally, owing to presence of the amorphous Si layer, the area of contact layers 111 is increased (since they not only exist on the exposed areas of the source/drain regions 110, but also exist on sidewalls of the contact holes 310 in the amorphous Si layer 251), therefore, the method for manufacturing a semiconductor structure provided by the present invention is capable of reducing contact resistance between source/drain regions and contact vias, and of improving performance of semiconductor devices as well.

In order for understanding of the semiconductor structure manufactured according to aforesaid method, the semiconductor structure is described here below with reference to FIG. 13.

With reference to FIG. 13, FIG. 13 illustrates a cross-sectional view of the semiconductor structure finally formed according to steps shown in FIG. 1. In the present embodiment, the semiconductor structure comprises: a substrate (100), a gate stack structure formed on the substrate (100), source/drain regions (110) formed within the substrate (100) and located on both sides of the gate stack structure, an amorphous Si layer (251) covering the source/drain regions (110), an interlayer dielectric layer (300) covering the amorphous Si layer (251) and the gate stack structure, and contact vias (320), which are made of a second conductive material, penetrating through the interlayer dielectric layer (300) and the amorphous Si layer (251) and being electrically connected with the source/drain regions (110). A contact layer (111) is formed between the contact vias (320) and the source/drain regions (110), and between the contact vias (320) and the amorphous Si layer (251).

The contact layer 111 is made of metal silicide, which may comprise either NiSi or Ni(Pt)Si_{2-y}, and may have a thickness in the range of 15 nm to 35 nm.

In another embodiment, the bottom of the contact vias 320 penetrates into the source/drain regions, so as to further increase area of the metal silicide layer 111 and to reduce contact resistance between the source/drain regions and the metal silicide layer.

Since composition, materials and formation methods of respective parts of the semiconductor structure in respective embodiments may be the same as embodiments of aforesaid method for manufacturing a semiconductor structure, thus they are not described here in detail in order not to obscure.

Although the exemplary embodiments and their advantages have been described in detail, it should be understood that various alternations, substitutions and modifications may be made to the embodiments without departing from the spirit of the present invention and the scope as defined by the appended claims. For other examples, it may be easily recognized by a person of ordinary skill in the art that the order of processing steps may be changed without departing from the scope of the present invention.

In addition, the scope to which the present invention is applied is not limited to the process, mechanism, manufacture, material composition, means, methods and steps described in the specific embodiments in the specification. According to the disclosure of the present invention, a person of ordinary skill in the art would readily appreciate from the disclosure of the present invention that the process, mechanism, manufacture, material composition, means, methods and steps currently existing or to be developed in future, which perform substantially the same functions or achieve substantially the same as that in the corresponding embodiments described in the present invention, may be applied according to the present invention. Therefore, it is intended that the scope of the appended claims of the present invention includes these process, mechanism, manufacture, material composition, means, methods or steps.

What is claimed is:

1. A method for manufacturing a semiconductor structure, comprising:
a) providing a substrate (100);
b) forming a dummy gate stack on the substrate (100), spacers (240) located on sidewalls of the dummy gate stack, and source/drain regions (110) located on both sides of the dummy gate stack, wherein the dummy gate stack at least comprises a first gate dielectric layer and a dummy gate (220):
c) forming an amorphous Si layer (251), which has the same doping type as the source/drain regions, on surfaces of the source/drain regions (110):
d) forming an interlayer dielectric layer (300) to cover the doped amorphous Si layer (251) and the dummy gate stack;
e) removing part of the interlayer dielectric layer (300) to expose the dummy gate stack;
f) removing the dummy gate stack to form an opening, filling the opening (260) with a second gate dielectric layer and a first conductive material (280) to form a gate stack structure; or removing part of the dummy gate stack that is located on the first gate dielectric layer to form an opening, and filling the opening (260) with a first conductive material (280) to form a gate stack structure;
g) forming contact holes (310) that penetrate through the interlayer dielectric layer (300) and the amorphous Si layer (251), wherein the contact holes (310) at least expose part of the source/drain regions (110):
h) forming a contact layer (111) on the exposed area of the source/drain regions (110) and on sidewalls of the contact holes (310) in the amorphous Si layer (251); and
i) filling the contact holes with a second conductive material to form contact vias (320).

2. The method of claim 1, wherein
at step c), the step for forming the doped amorphous Si layer (251) comprises:
forming an amorphous Si layer (250) to cover the dummy gate stack, spacers (240) located on sidewalls of the dummy gate stack, and source/drain regions (110) located on both sides of the dummy gate stack;
doping the amorphous Si layer (250), wherein the doping type thereof is the same as that of the source/drain regions; and
patterning the amorphous Si layer (250) to keep the amorphous Si layer on the source/drain regions and remove the remaining amorphous Si layer, so as to form the doped amorphous Si layer (251).

3. The method of claim 1, wherein between the step f) and the step g), the method further comprises:
j) forming a cap layer (400) to cover the gate stack structure and the interlayer dielectric layer (300), wherein the material of the cap layer (400) is different from the material of the interlayer dielectric layer (300).

4. The method of claim 1, wherein the contact layer (111) comprises one of NiSi and Ni(Pt)Si_{2-y}.

5. The method of claim 1, wherein the step h) comprises:
forming a metal layer to cover the exposed area of the source/drain regions (110) and sidewalls of the contact holes (310);
implementing a first annealing such that the metal layer reacts with the exposed area of the source/drain regions (110) and with sidewalls of the contact holes (310) in the amorphous Si layer (251) so as to form a contact layer (111); and
removing the unreacted metal layer.

6. The method of claim 5, wherein
the metal layer comprises one of Ni and NiPt.

7. The method of claim 5, wherein
if the material of the metal layer is NiPt, the content of Pt therein is less than 5%.

8. The method of claim 5, wherein the metal layer has a thickness that ranges from 10 nm to 25 nm.

9. The method of claim 5, wherein
the annealing is performed at a temperature between 500° C. to 600° C.

10. The method of claim 5, wherein the contact layer (111) has a thickness that ranges from 15 nm to 35 nm.

11. The method of claim 1, wherein prior to filling the first conductive material (280), the step f) further comprises:
implementing a second annealing to repair the structure that has been formed before filling the first conductive material.

12. A semiconductor structure, which comprises:
a substrate (100);
a gate stack structure formed on the substrate (100);
source/drain regions formed within the substrate (100) and located on both sides of the gate stack structure;
a doped amorphous Si layer (251) that covers the source/drain regions (110);
an interlayer dielectric layer (300) that covers the doped amorphous Si layer (251) and the gate stack structure;
contact vias (320), which are made of a second conductive material, penetrating through the interlayer dielectric layer (300) and the amorphous Si layer (251) and being electrically connected with the source/drain regions (110); wherein
a contact layer (111) is formed between the contact vias (320) and the source/drain regions (110), and between the contact vias (320) and the amorphous Si layer (251).

13. The semiconductor structure of claim 12, wherein
the contact layer (111) comprises one of NiSi and Ni(Pt)Si_{2-y}.

14. The semiconductor structure of claim 12, wherein
the contact layer (111) has a thickness that ranges from 15 nm to 35 nm.

15. The semiconductor structure of claim 12, wherein
the contact vias (320) penetrate into the source/drain regions (110).

16. The method of claim 6, wherein
the metal layer has a thickness that ranges from 10 nm to 25 nm.

17. The method of claim 6, wherein
the annealing is performed at a temperature between 500° C. to 600° C.
